(19) United States
(12) Patent Application Publication
(10) Pub. No.: US 2014/0298839 A1
(43) Pub. Date: Oct. 9, 2014

(54) AIR-CONDITIONING SYSTEM

(71) Applicant: FUJITSU LIMITED, Kawasaki-shi (JP)

(72) Inventors: Ikuro NAGAMATSU, Yokohama (JP); Junichi Ishimine, Kawasaki (JP); YUJI OHBA, Hadano (JP); Tomoko Kutsuzawa, Yokohama (JP); Masahiro Takanashi, Yokohama (JP); MASAYUKI TATEWAKI, Yokohama (JP)

(21) Appl. No.: 14/310,048

(22) Filed: Jun. 20, 2014

Related U.S. Application Data
(63) Continuation of application No. PCT/JP2012/051959, filed on Jan. 30, 2012.

(51) Int. Cl. H05K 7/20; G06F 1/20

(52) U.S. Cl. CPC H05K 7/20209; G06F 1/206; H05K 7/20145; H05K 7/20718
USPC 62/186; 165/296

(57) ABSTRACT

There are provided a divider that divides a cold aisle and a hot aisle in a chamber in which an information technology device is to be enclosed and a rectifier that is formed in a shape of a hollow tube and is provided so as to penetrate the divider. There are also provided a detector that is built into the rectifier and detects airflow passing through the rectifier, and a controller that controls an amount of air supplied to the cold aisle using detection results of the detector.

### CROSS-REFERENCE TO RELATED APPLICATION

This application is a continuation application of International Application PCT/JP2012/051959, filed on Jan. 30, 2012 and designated the U.S., the entire contents of which are incorporated herein by reference.

### FIELD

The embodiments discussed herein are related to an air-conditioning system that manages air-conditioning in a chamber in which information technology devices (IT devices) are to be enclosed.

### BACKGROUND

IT devices (Information Technology Devices), such as a server machine, a storage system, and a network device, and an IT device mounting rack on which IT devices are stacked are installed in a chamber that is called a data center, a machine room, or a server room. Functional components, such as a CPU (Central Processing Unit), a GPU (Graphics Processing Unit), a memory, and a HDD (Hard Disk Drive), are built into each of these IT devices, and heat is generated as the result of the power consumption of the respective functional components.

Meanwhile, to ensure the reliability or operation of the IT device, it is important to cool the respective functional components so that the functional components do not retain heat. For this reason, a general IT device is subjected to air-cooling type temperature management using cooling air that is externally supplied into the IT device. An electric axial fan is often used for taking in cooling air. The rotating speed of the electric axial fan is controlled, depending on an operating state or a load of the IT device.

Incidentally, there is a concern that heat discharged from IT devices may affect the operation of other IT devices in a room in which a plurality of IT devices are installed. In particular, since a server machine, which is installed in a large-scale data center, includes a plurality of functional components integrated into a server rack, the amount of heat generated from the server machine is large and the server machine also significantly affects adjacent server machines.

From this viewpoint, as an existing data center in the related art, there is a data center employing a cooling method in which IT devices are arranged in a row to divide a chamber space into two spaces and cooling air supplied to one space is made to flow to the other space. That is, a plurality of rack rows formed of IT devices of which intake surfaces and exhaust surfaces face the same directions are prepared, and the rack rows are arranged so that the intake surfaces of adjacent rack rows face each other and the exhaust surfaces of adjacent rack rows face each other.

In this arrangement structure, cooling air is supplied to a space that is surrounded by the intake surfaces and air is exhausted from a space that is surrounded by the exhaust surfaces. Accordingly, exhaust heat can be exhausted in a predetermined direction, so that heat distribution in the room is easily adjusted. Meanwhile, since the space surrounded by the intake surfaces is a space to which cooling air is always supplied, the space surrounded by the intake surfaces is called a cold aisle. Likewise, since the space surrounded by the exhaust surfaces is a space in which exhaust heat of the IT devices flows, the space surrounded by the exhaust surfaces is called a hot aisle.

Further, a technique, which improves cooling efficiency in a room by providing a dividing wall between the cold aisle and the hot aisle, is also used. That is, the leakage of cooling air, which is supplied to the cold aisle, to the hot aisle is prevented, and the back flow of exhaust heat from the hot aisle to the cold aisle is prevented. This type is called a chamber type, and the structures of various variations, such as a structure in which the ceiling surface of the hot aisle is closed and a structure in which the ceiling surface of the cold aisle is closed, are provided.

However, in a chamber-type cooling structure, a pressure difference may be generated between the space of the cold aisle and the space of the hot aisle. That is, when the amount of cooling air supplied to the cold aisle is smaller than the amount of air blown by an axial fan that is built into an IT device, pressure in the cold aisle becomes lower than pressure in the hot aisle. On the contrary, when the amount of cooling air supplied to the cold aisle is larger than the amount of air blown by the axial fan, pressure in the cold aisle becomes higher than pressure in the hot aisle.

The leakage of cooling air and the leakage of exhaust heat from an unintended portion occur due to this pressure difference, so that turbulent heat distribution may be formed. Further, when pressure in the hot aisle is higher than pressure in the cold aisle, a load applied to the axial fan of the IT device is increased. For this reason, the efficiency of cooling the IT device may deteriorate. Furthermore, since the amount of air blown by the axial fan is changed according to the operating state or the load of the IT device, the flow rate of cooling air to be supplied to the cold aisle is not always constant and it is difficult to appropriately control the flow rate of cooling air to be supplied to the cold aisle.

A technique, which prevents the generation of a pressure difference by forming an opening portion in a dividing wall, is proposed to solve the above-mentioned problem. That is, in this technique, cooling air and exhaust heat are allowed to flow through the opening portion, and the amount of cooling air to be supplied is controlled so that the flow rate of air passing through the opening portion becomes zero. According to this technique, it is possible to adjust the amount of cooling air to be supplied while keeping the balance of pressure in chamber spaces (q.v. Japanese Laid-open Patent Publication No. 2009-257730).

However, a low flow rate of air, which is close to zero, is detected with a high degree of accuracy in order to accurately control the amount of cooling air to be supplied so that air does not flow through the opening portion. Accordingly, since an expensive sensor having high sensing accuracy is used, there is a problem in that cost is increased.

Further, since the amount of heat, which may be generated in the IT devices, is changed according to the operating states or the loads of the respective IT devices, the heat distribution in the hot aisle may become non-uniform. When air flows through the opening portion in a state in which the thermal distribution becomes non-uniform, the flow direction of air is not always perpendicular to the opening portion. Accordingly, the flow rate of air passing through the opening portion is not accurately detected in a sensor that has directionality in terms of the detection of a flow rate or flow velocity. That is, a non-directional sensor, which substantially does not have directionality in terms of the detection of a flow rate or flow velocity, is provided near the opening portion to accurately detect the flow rate of air passing through the opening portion.

Meanwhile, since the flow direction of air flowing through the opening portion is not always constant, it is very difficult to distinguish whether a flow rate detected by a non-directional sensor, which does not have directionality, is the flow rate of air actually passing through the opening portion or is the flow rate of air caused by the convection generated by thermal unevenness in the hot aisle.

As described above, the related art has a problem in that it is difficult to reduce the cost of the air-conditioning system according to sensing. Further, even if a high-end sensor is applied, it is difficult to accurately detect the air flow passing through the opening portion formed at the dividing wall provided between the cold aisle and the hot aisle. As a result, there is a problem in that it is difficult to improve the controllability of an air-conditioning system.

### SUMMARY

According to an aspect of the embodiments, an air-conditioning system includes a divider that divides a cold aisle and a hot aisle in a chamber in which an information technology device is to be enclosed, and a rectifier that is formed in a shape of a hollow tube and provided so as to penetrate the divider. Further, the air-conditioning system includes a detector that is built into the rectifier and detects airflow passing through the rectifier, and a controller that controls an amount of air supplied to the cold aisle using detection results of the detector.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an example perspective view illustrating the entire structure of an air-conditioning system as a first embodiment;

FIG. 2 is an example schematic cross-sectional view of a chamber to which the air-conditioning system of FIG. 1 is applied.

FIGS. 3A, 3B and 3C are example perspective views illustrating a rectifying unit;

FIG. 4A is an example schematic cross-sectional view of a chamber to which an air-conditioning system as a second embodiment is applied;

FIG. 4B is an example schematic perspective view of a rectifying unit into which sensors are built;

FIG. 4C is an example graph illustrating the change of temperature detected by the sensors; and

FIG. 5 is an example flowchart illustrating a control procedure of the air-conditioning system of FIGS. 4A to 4C.

### DESCRIPTION OF EMBODIMENTS

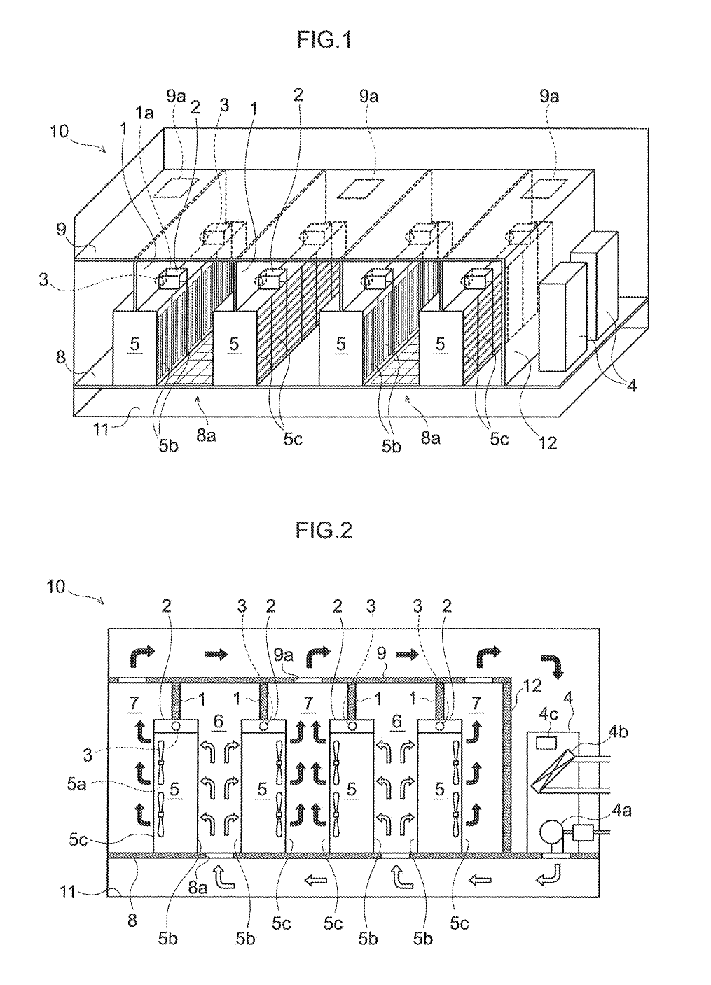

Embodiments will be described below with reference to the drawings. However, the embodiments to be described below are merely exemplary, and the application of various modifications or techniques, which are not illustrated in the embodiments, is not intended to be excluded. That is, the following embodiments may have various modifications without departing from the scope of the invention. Meanwhile, in FIGS. 1 to 5, the same elements are denoted by the same reference numerals.

### 1. Structure of First Embodiment

An air-conditioning system according to a first embodiment is applied to a server room 10 illustrated in FIG. 1. Information technology devices (IT devices, devices for information technology, information processing devices), such as a server machine, a storage system, and a network device, and an IT device mounting rack (server rack) on which IT devices are stacked are installed in the server room 10. Hereinafter, these are collectively referred to as IT devices 5. Usage environment conditions, such as the ranges of operating temperature and operating humidity under which the IT devices stably operate, are determined for the IT devices 5. For this reason, indoor temperature and indoor humidity are always controlled in the general server room 10 by an air-conditioning device 4 (controller). Accordingly, room temperature and humidity of the server room 10 are maintained in predetermined ranges that satisfy the usage environment conditions of the IT devices 5.

[1-1. Server Room]

As illustrated in FIG. 1, a double floor 8 and a suspended ceiling 9 are provided in the server room 10. The double floor 8 is a floor in which a movable raised floor (free access floor) is provided above a floor structure (slab) so as to secure a space for wiring and piping. A power supply for the IT devices 5 and wiring materials for communication are disposed in a space, which is interposed between a slab 11 and the double floor 8 and formed under the floor, (hereinafter, referred to as “under the floor”) using an arrangement plan that corresponds to the types, the number, the sizes, and the like of the IT devices 5. Further, in the server room 10, the space under the floor is used as not only a wiring space for power supply cables or communication cables of the IT devices 5 but also a duct space for a blown air (air-conditioned air) sourced from the air-conditioning device 4.

Ceiling joists and ceiling joist receivers (cradlings), which are assembled in the shape of a lattice, are suspended from a floor structure (a slab of an immediate upper floor, not illustrated) of an immediate upper floor, so that a base member is formed. Then, a ceiling board or a finishing material is mounted on an underside of the base member, so that the suspended ceiling 9 is formed. An attic space, which is interposed between the suspended ceiling 9 and the slab of the immediate upper floor, (hereinafter, simply referred to as an attic) is used as not only an installation space for lighting fixtures but also a duct space for air-conditioning.

A space between the double floor 8 and the suspended ceiling 9 is a chamber space in which the IT devices 5 are installed. As described above, the server room 10 is mainly divided into three stories, that is, a space under the floor, a chamber, and the attic by the double floor 8 and the suspended ceiling 9. The blown air, which is supplied from the air-conditioning device 4, is sent to the chamber space through the space under the floor, and is discharged to the attic.

In this embodiment, the chamber space is divided into two chambers by a partition wall 12 that is erected from the double floor 8 to the height of the suspended ceiling 9. A portion of the suspended ceiling 9, which is positioned in one chamber space, is removed, and the air-conditioning device 4 is disposed in the one chamber space. That is, as illustrated in FIG. 2, the space in which the air-conditioning device 4 is disposed is formed integrally with the attic and the space is separated from the other chamber space. Further, the air-conditioning device 4 has a function to take in air of a surrounding space including the attic and to supply the blown air to the space under the floor after performing a predetermined air-conditioning treatment.

A circulation path of the blown air is accordingly formed, on which the blown air supplied from the air-conditioning device 4 flows from the space under the floor, through the chamber space, to the attic. And the blown air is taken into the air-conditioning device 4 again. Meanwhile, white arrows of FIG. 2 represent a flow path of the blown air of which temperature and humidity have been adjusted by the air-conditioning device 4, and black arrows of FIG. 2 represent a flow path of air of which temperature has been raised by the exhaust heat of the IT devices 5.

[1-2. IT Devices]

Functional components, such as a CPU, a GPU, a memory, and a HDD, are built into each IT device 5. Further, as illustrated in FIG. 2, each IT device 5 is provided with fans 5a that discharge heat generated from the functional component to the outside of each IT device 5. For example, the axial fans 5a are provided near a back surface 5c in each of rectangular parallelepiped IT devices 5, and are fixed so that rotating shafts of the fans are substantially perpendicular to the back surface 5c. Each of the front surface 5b and the back surface 5c of each IT device 5 is provided with perforated metal board or a mesh cover. In this case, the air is taken in from the front surfaces 5b of IT devices 5 and discharged from the back surfaces 5c of the IT devices 5, so that air flow is formed.

In this embodiment, as illustrated in FIGS. 1 and 2, the IT devices 5 are disposed so that the directions of the front surfaces 5b and the back surfaces 5c are aligned with those of the IT devices 5 laterally adjacent to each other. Hereinafter, the plural of IT devices 5, of which the directions of the front surfaces 5b and the back surfaces 5c are aligned with each other so as to become the same directions, are referred to as a rack row. The respective rack rows are disposed substantially parallel to each other in the server room 10 so that the front surfaces 5b or the back surfaces 5c of adjacent rack rows face each other.

Since spaces, which face the front surfaces 5b of the rack rows, are spaces to which low-temperature blown air for cooling the IT devices 5 is supplied from the air-conditioning device 4, the spaces facing the front surfaces 5b are referred to as cold aisles 6. The cold aisle 6 is a space of the chamber to which air for cooling the IT device 5 is supplied. Floor surfaces of the cold aisles 6 are provided with floor opening portions 8a through which the blown air is taken in from the space under the floor.

Meanwhile, since spaces, which face the back surfaces 5c of the rack rows, are spaces to which air warmed by the exhaust heat of the IT devices 5 is discharged, the spaces facing the back surfaces 5c are referred to as hot aisles 7. The hot aisle 7 is a space of the chamber to which the air having passed through the IT device 5 is discharged. Ceiling surfaces of the hot aisles 7 are provided with ceiling opening portions 9a through which exhaust heat is discharged to the attic. Meanwhile, a lattice-shaped grating, perforated metal through which a plurality of round holes are formed, or the like is mounted on each of the floor opening portions 8a and the ceiling opening portions 9a.

The blowing efficiency and the rotational speed of the fans 5a of the IT devices 5 are appropriately set according to the amount of heat generated from the IT devices 5, the usage environment conditions of the IT devices 5, or the like. Meanwhile, if the amount of the blown air supplied from the air-conditioning device 4 is smaller than the amount of air passing through the IT devices 5, pressure on the downstream side of the fans 5a becomes higher than pressure on the upstream side of the fans 5a. For this reason, a load applied to the fans 5a is increased. Meanwhile, if the amount of the blown air supplied from the air-conditioning device 4 is larger than the amount of air passing through the IT devices 5, a load applied to the fans 5a is reduced.

However, in this case, the flow of air from an unintended portion is likely to be generated since pressure in the cold aisles 6 is increased. For example, the blown air leaks to the attic or other spaces without passing through the inside of the IT devices 5, so that an energy loss in air-conditioning is increased. Accordingly, it is preferable that the amount of the blown air supplied from the air-conditioning device 4 is controlled according to the amount of air passing through the IT devices 5. The air-conditioning system of this embodiment appropriately controls the amount of the blown air by being provided with elements for air-conditioning control to be described below.

[1-3. Element for Air-Conditioning Control]

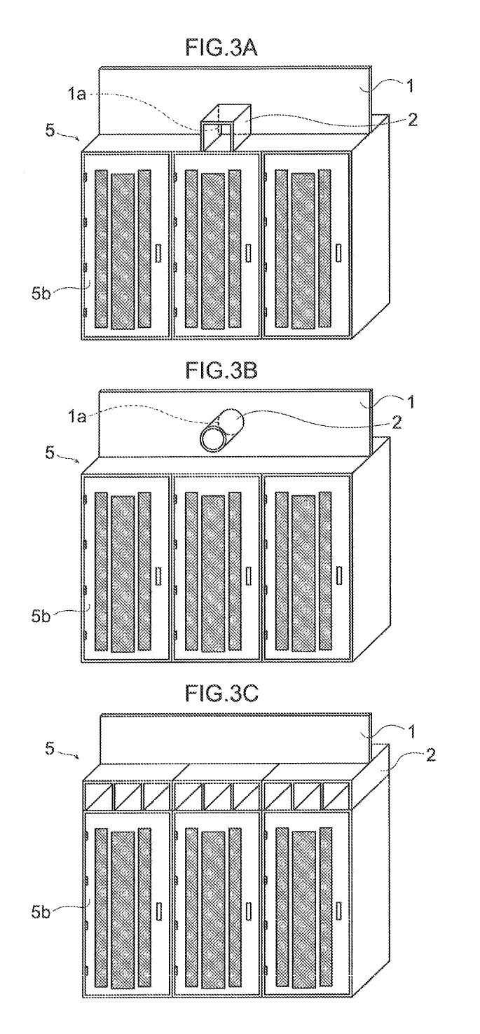

As illustrated in FIG. 1, a dividing wall 1 (dividing element, divider), which forms a boundary plane between the cold aisle 6 and the hot aisle 7, is provided on each rack row. The dividing wall 1 is a hanging wall that is suspended from the suspended ceiling 9 to a position of the top surfaces of the IT devices 5. The dividing wall 1 has a function to divide the cold aisle 6 and the hot aisle 7. Meanwhile, since the dividing wall 1 is provided with opening portions 1a as illustrated in FIG. 3A, the flow of air is allowed between the cold aisle 6 and the hot aisle 7.

That is, the cold aisle 6 and the hot aisle 7 are not completely separated from each other by the dividing wall 1. However, the opening portions 1a are not formed to make air actively flow between the cold aisle 6 and the hot aisle 7. Even though the opening portions 1a have a structure in which the flow of air is allowed, the opening portions 1a are formed to control the amount of the air so that the air hardly flows. In other words, the opening portions 1a are formed to confirm a state in which air does not flow.

The dividing wall 1 is provided with hollow-tubular rectifying units 2 (rectifiers) that penetrate through the opening portions 1a. The rectifying units 2 are disposed so that tubular axes of the rectifying units 2 are perpendicular to the dividing wall 1. The cross-sectional shape of each rectifying unit 2 corresponds to the outline of the opening portions 1a. Preferably, the rectifying units 2 are tightly fitted to the opening portions 1a. In an example illustrated in FIG. 3A, the cross-sectional shape of the opening portion 1a and the rectifying unit 2 is a square shape (a regular tetragon), and the internal dimensions of the opening portion 1a are made to be equal to the external dimensions of the rectifying unit 2. In other words, the shape of the rectifying unit 2 is the shape of a hollow quadrangular tube and a tubular axis of the rectifying unit 2 is straight (is not bent). The dimension of the rectifying unit 2 in a longitudinal direction (a direction along the tubular axis) is arbitrary, and, for example, may be equal to or smaller than the dimensions of the IT devices 5 in a front-back direction (a dimension between the front surface 5b and the back surface 5c) in consideration of workability.

The rectifying unit 2 has a function of rectifying the flow direction of air flow along the tubular axis when the air flow (the flow of air) is generated in a hollow portion that communicates with the cold aisle 6 and the hot aisle 7. That is, when the dividing wall 1 is provided with only the opening portions 1a, the direction of air flow is inconstant. In contrast, when the dividing wall 1 is provided with the rectifying units 2, the direction of air flow is rectified to the direction of the tubular axis.

A sensor 3 (detector), which detects air flow passing through the hollow portion of each rectifying unit 2 in the direction of the tubular axis, is provided in each rectifying unit 2. Dynamic sensors (motion detectors) for detecting the movement of air flow, such as a hot-wire anemometer for detecting the flow velocity (the moving distance per unit time) of air flow and a mass flow meter for detecting the flow rate of air (the flow volume of air passing through a predetermined cross-section for unit time), are used as the sensor 3. The number of dynamic sensors to be installed in one rectifying unit 2 may be at least one.

Further, the position of the sensor 3 in the cross-section, which is obtained when the hollow portion of the rectifying unit 2 is cut along the surface of the dividing wall 1, is set to an arbitrary position according to the shape or characteristics of the sensor 3. Typically, the position of the sensor 3 is set so that a detection element of the sensor 3 is positioned near the central portion of the hollow portion. Information detected by the sensor 3 is transmitted to the air-conditioning device 4.

The air-conditioning device 4 is an air conditioner that adjusts the heating/cooling and humidity of the server room 10, that is, controls the operating environments of the IT devices 5. As illustrated in FIG. 2, a fan 4a, a heat exchanger 4b, and a control unit 4c are provided in the air-conditioning device 4. The fan 4a has a function of taking in the surrounding air, flowing the air near the heat exchanger 4b, and supplying the air to the space under the floor in the server room 10. The heat exchanger 4b is a unit for cooling and heating air. Since a refrigerant (heat medium) flows in a core of the heat exchanger 4b, the heat exchanger 4b adjusts the temperature of air by transferring heat between the refrigerant and the air, which is present on the outer surfaces of a plurality of fins formed on the core. The refrigerant is supplied from a chiller, a heat source device, or the like (not illustrated).

The control unit 4c is an electronic control unit that controls the operation of the fan 4a and the heat exchanger 4b, and is, for example, an LSI device (Large Scale Integration device) or an electronic device where a microprocessor, a ROM (Read Only Memory), a RAM (Random Access Memory), and the like are integrated or incorporated. The control unit 4c has a function of controlling the rotational speed of the fan 4a and the temperature of the refrigerant of the heat exchanger 4b using the information that is transmitted from the sensors 3. In this embodiment, the amount of the blown air supplied from the air-conditioning device 4 is controlled so that the flow of air is not generated in the rectifying unit 2.

For example, the control unit 4c increases the rotational speed of the fan 4a to increase the amount of the blown air when the flow of air from the hot aisle 7 to the cold aisle 6 is generated. Meanwhile, the control unit 4c reduces the rotational speed of the fan 4a to reduce the amount of the blown air when the flow of air from the cold aisle 6 to the hot aisle 7 is generated. The direction of the flow of air is determined from the flow velocity or the flow rate of air that is detected by the sensor 3.

In principle, it is possible to find out the presence or absence of the flow of air by determining whether or not the flow rate or the flow velocity detected by the sensor 3 is zero. Meanwhile, it may also be possible to find out the presence or absence of the flow of air by determining whether or not the absolute value of the flow rate or the flow velocity is equal to or smaller than a predetermined value in consideration of limitation that is caused by the sensing resolution of the sensor 3.

Meanwhile, the flow rate of fluid (the volume of fluid flowing per unit time), which flows in a general tubular body, is expressed as a product of the flow velocity and the cross-sectional area. Since the cross-sectional area is uniquely given from the shape of the hollow portion, one of the flow rate and the flow velocity can be calculated from the other thereof. Accordingly, if a sensor detecting at least one of the flow velocity and the flow rate is provided, the above-mentioned control can be performed. In addition, the above-mentioned control may be performed using a sensor that detects a physical quantity correlating with one of the flow velocity and the flow rate.

### 2. Operation

When the amount of the blown air supplied from the air-conditioning device 4 is larger than the amount of air passing through the IT devices 5, pressure on the upstream side of the IT devices 5 becomes higher than pressure on the downstream side of the IT devices 5. For this reason, the flow of air from the cold aisle 6 to the hot aisle 7 is generated in the rectifying unit 2. At this time, the flow of air is rectified to a direction along the tubular axis of the rectifying unit 2, so that the direction of air flow is rectified to a direction that is perpendicular to the opening portion 1a of the dividing wall 1. Accordingly, the value of the flow velocity or the flow rate of air, which is detected by the sensor 3, becomes an accurate value, so that detection accuracy is improved. Highly accurate information of the flow of air is transmitted to the control unit 4c of the air-conditioning device 4, so that the rotational speed of the fan 4a is controlled so as to be reduced.

Meanwhile, when the amount of the blown air supplied from the air-conditioning device 4 is smaller than the amount of air passing through the IT devices 5, pressure on the upstream side of the IT devices 5 becomes lower than pressure on the downstream side of the IT devices 5. For this reason, the flow of air from the hot aisle 7 to the cold aisle 6 is generated in the rectifying unit 2. Meanwhile, the flow of air is rectified to a direction along the tubular axis of the rectifying unit 2, so that the direction of air flow is rectified to a direction that is perpendicular to the opening portion 1a of the dividing wall 1. Accordingly, detection accuracy is improved, so that highly accurate information of the flow of air is transmitted to the control unit 4c of the air-conditioning device 4. The flow direction of air at this time is opposite to the flow direction that is obtained when the amount of the blown air supplied from the air-conditioning device 4 is large. Accordingly, the rotational speed of the fan 4a is controlled so as to be increased.

Due to this control, the flow velocity or the flow rate of air, which is detected by the sensor 3, gradually approaches zero. As a result, the flow of air between the cold aisle 6 and the hot aisle 7 is hardly generated. That is, since all of the blown air supplied to the cold aisles 6 flows into the hot aisle 7 through the inside of the IT devices 5, the efficiency of the cooling of the IT devices 5 is improved. Further, since there is no excess and deficiency of the amount of the blown air supplied to the cold aisles 6, energy efficiency in air-conditioning is improved.

### 3. Effect

As described above, according to the air-conditioning system of this embodiment, the following effects are obtained.

(1) Since the rectifying unit 2 is fitted to the opening portion 1a of the dividing wall 1 forming the boundary plane between the cold aisle 6 and the hot aisle 7, it is possible to appropriately rectify air flow. Accordingly, since it is possible to improve the detection accuracy of the sensor 3 that is provided in the rectifying unit 2 and to accurately control the amount of air that is supplied to the cold aisle 6, it is possible to improve the controllability of the air-conditioning system.

In particular, since it is possible to make the flow of air around the sensor 3 constant (stable) as compared to a case in which the rectifying unit 2 is not provided around the opening portion 1a, it is possible to improve detection accuracy and it is also needless to prepare a sensor that does not have directionality. (That is, non-directional sensors can be used well.) Further, it is possible for the rectifying unit 2 to suppress the influence of convection that may be generated by thermal unevenness in the hot aisle 7.

Accordingly, it is needless to distinguish whether the detection result of the sensor is the flow rate of air actually passing through the opening portion 1a or is the flow rate of air caused by the convection generated by thermal unevenness in the hot aisle 7. Even in this regard, it is possible to improve the accuracy of detection of the amount of air. Accordingly, it is possible to improve the controllability of the air-conditioning system.

(2) Furthermore, in the air-conditioning system, the sensor 3, which detects the flow velocity or the flow rate of air flow, is built into the rectifying unit 2. Accordingly, it is possible to accurately determine whether or not the flow of air is generated between the cold aisle 6 and the hot aisle 7 (that is, whether movement (motion) of air is detected or not). Therefore, it is possible to improve the accuracy of control of the amount of air that is supplied to the cold aisle 6.

(3) In addition, in the air-conditioning system, the hollow-tubular rectifying unit 2 is provided so as to be perpendicular to the dividing wall 1. Accordingly, it is possible to improve an effect of rectifying the flow of air passing through the rectifying unit 2. Further, since the shape of the entire inner surface of the rectifying unit 2 is parallel to the flow of air passing through the rectifying unit 2, it is possible to reduce the resistance of a flow passage. Accordingly, it is possible to further improve the accuracy of detection of the flow of air. Therefore, it is possible to improve the reliability in controlling the amount of air supplied to the cold aisle 6.

### 4. Structure of Second Embodiment

[4-1. Element for Air-Conditioning Control]

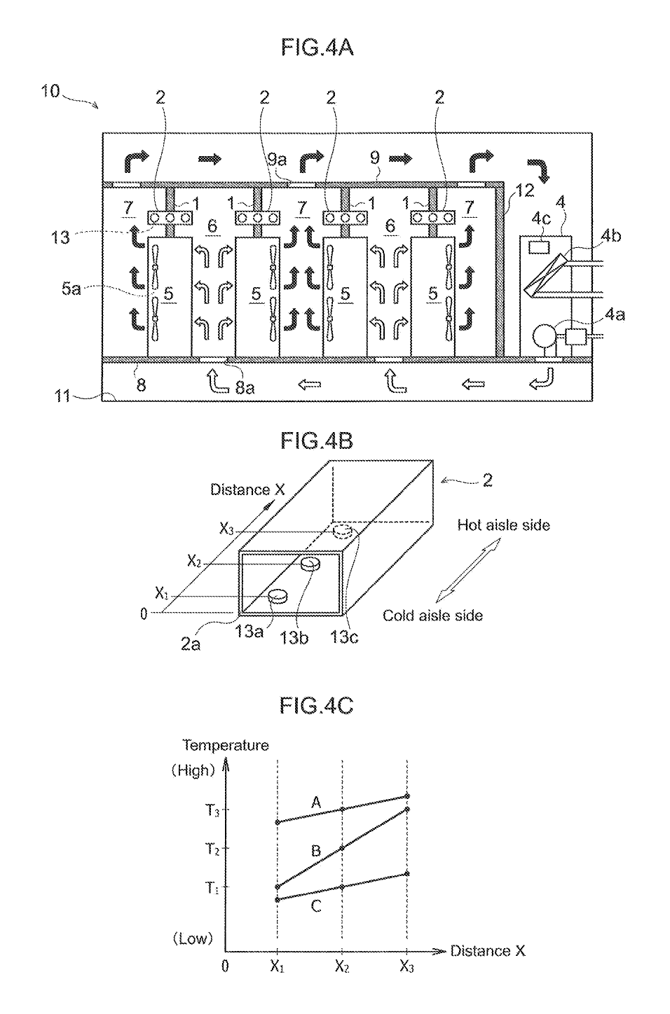

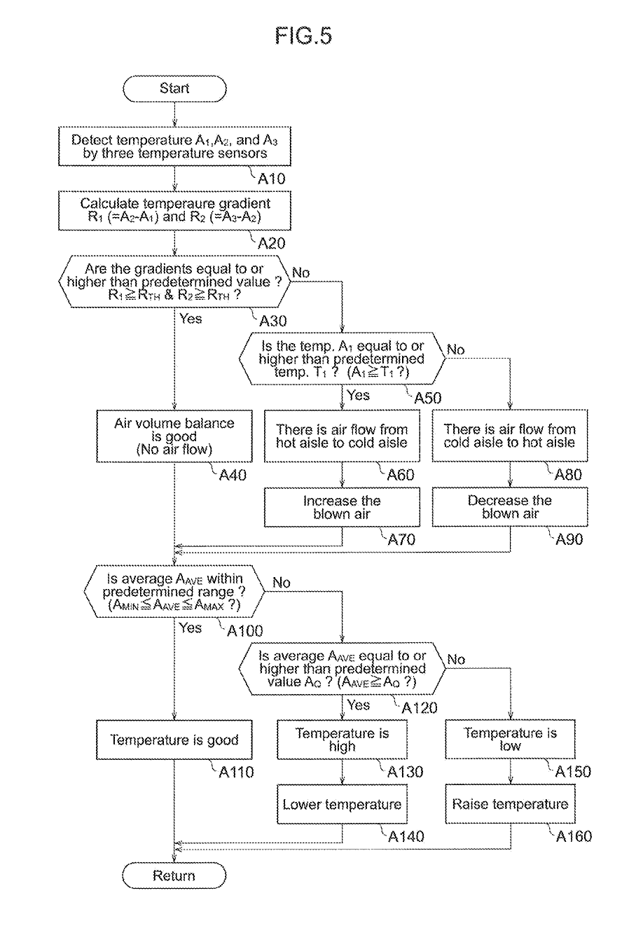

As illustrated in FIG. 4A, an air-conditioning system according to a second embodiment includes a plurality of sensors 13 instead of the sensor 3 that is built into each rectifying unit 2 of the first embodiment. These sensors 13 are static sensors (state detectors), such as temperature sensors (thermocouples, thermistors, or the like) for detecting the temperature of air or pressure sensors for detecting the pressure of air. Unlike the dynamic sensors, it is preferable that the number of static sensors to be installed in one rectifying unit 2 may be two or more.

In this embodiment, as illustrated in FIG. 4B, three sensors 13 are provided along a tubular axis of the rectifying unit 2. Distances between an end portion 2a of the rectifying unit 2, which is close to the cold aisle 6, and the respective sensors 13 along the tubular axis are denoted by X₁, X₂, and X₃, and the sensors 13 detect temperatures A₁, A₂, and A₃ at the positions thereof, respectively. Information of these temperatures A₁, A₂, and A₃ is transmitted to the control unit 4c of the air-conditioning device 4.

[4-2. Control Method]

When the flow of air from the hot aisle 7 to the cold aisle 6 is generated in the rectifying unit 2, the control unit 4c performs control to increase the rotational speed of the fan 4a. Further, when the flow of air in an opposite direction is generated, the control unit 4c performs control to reduce the rotational speed of the fan 4a. To find out the presence or absence of the flow of air, there are two methods. A first method is a method based on at least one or more of the values of temperatures A₁, A₂, and A₃. A second method is a method based on a temperature gradient in the rectifying unit 2.

Here, a relationship between temperature distribution and the flow of the air in the rectifying unit 2 will be described.

If the flow of air is not generated in the rectifying unit 2, it is considered that a temperature detected by a sensor 13a disposed close to the cold aisle 6 becomes a predetermined temperature T₁ close to the room temperature of the cold aisle 6. That is, the detected temperature is almost the same temperature of the blown air supplied from the air-conditioning device 4. Further, a temperature detected by a sensor 13c disposed close to the hot aisle 7 becomes a predetermined temperature T₃ that is obtained by adding a temperature rise caused by the exhaust heat of the IT devices 5 to the room temperature of the cold aisle 6. A temperature detected by a sensor 13b disposed near the middle of the rectifying unit 2 becomes a predetermined temperature T₂ that is obtained from the internal division between the predetermined temperatures T₁ and T₃ according to a position.

Accordingly, if the temperature of the blown air set by the air-conditioning device 4 or the amount of heat discharged from the IT devices 5 is known, it is possible to obtain or previously estimate values of these predetermined temperatures T₁, T₂, and T₃. As illustrated in FIG. 4C, the graph denoted by reference character B is obtained. The temperature distribution is obtained when the flow of air is not generated in the rectifying unit 2. In the above-mentioned first method, the rotational speed of the fan 4a is controlled so that at least one of the temperatures A₁, A₂, and A₃ comes close to predetermined temperatures (predetermined temperatures T₁, T₂, and T₃) corresponding to the respective temperatures while using a state, which is represented by the graph of reference character B, as a target state of temperature distribution.

For example, it is considered to control the rotational speed of the fan 4a so that the temperature A₁ comes close to the predetermined temperature T₁ or to control the rotational speed of the fan 4a so that the temperature A₂ comes close to the predetermined temperature T₂. Alternatively, the rotational speed of the fan 4a may be controlled so that the three temperatures A₁, A₂, and A₃ come close to the predetermined temperatures T₁, T₂, and T₃, respectively.

The first method is a method that can control the amount of the blown air when at least one or more sensors 13 are provided in the rectifying unit 2, and is a method having a large merit in terms of the simple structure and cost of a device.

Meanwhile, the state of temperature distribution in the rectifying unit 2 is not uniformly changed according to the amount of the blown air. For example, when the amount of the blown air is reduced in the state of reference character B of FIG. 4C, a detection value of the sensor 13a disposed close to the cold aisle 6 is more increased than a detection value of the sensor 13c disposed close to the hot aisle 7 as illustrated in FIG. 4C by reference character A. The graph of reference character A represents that the room temperature of the cold aisle 6 is raised by two factors of “the reduction of the amount of the blown air” and “the inflow of exhaust heat from the hot aisle 7”.

On the contrary, when the amount of the blown air is increased in the state of reference character B of FIG. 4C, a detection value of the sensor 13c disposed close to the hot aisle 7 is more reduced than a detection value of the sensor 13a disposed close to the cold aisle 6 as illustrated in FIG. 4C by reference character C. The graph of reference character C represents that the room temperature of the hot aisle 7 is lowered by two factors of “the increase of the amount of the blown air” and “the flow of the blown air to the hot aisle 7”.

As described above, the variation of temperature, which is obtained when the amount of the blown air is changed by a unit amount, varies depending on positions in the rectifying unit 2, and represents opposite characteristics when the amount of the blown air is large as compared to the state of reference character B and when the amount of the blown air is small as compared to the state of reference character B. For this reason, there is a case in which the accuracy of control is not easily improved according to the positions of the sensors 13 or the number of the sensors 13.

For example, when the amount of the blown air is deficient, the variation of temperature at the sensor 13a, which is disposed close to the cold aisle 6, sensitively responds to the deficit of the blown air. However, when the amount of the blown air is sufficient, the responsiveness of the variation of temperature to the surplus of the blown air becomes dull. On the contrary, when the amount of the blown air is sufficient, the variation of temperature at the sensor 13c, which is disposed close to the hot aisle 7, can ensure high sensing accuracy about the surplus of the blown air. However, when the amount of the blown air is deficient, sensing accuracy is reduced.

In the above-mentioned second method, the amount of the blown air is controlled from this viewpoint, using a temperature gradient in the rectifying unit 2. The second method is a method that can control the amount of the blown air when at least two or more sensors 13 are provided in the rectifying unit 2, and is a method that can improve the accuracy of control of the amount of the blown air as compared to the first method.

As illustrated in FIG. 4C, when the flow of air is not generated between the cold aisle 6 and the hot aisle 7, a temperature gradient in the rectifying unit 2 becomes the maximum (that is, a steep gradient). Further, as the flow of air becomes stronger, the temperature gradient in the rectifying unit 2 is reduced (that is, a gentle gradient). Accordingly, when the temperature gradient is equal to or larger than a predetermined gradient, the control unit 4c determines that the flow of air is not generated in the rectifying unit 2. When the temperature gradient is smaller than a predetermined gradient, the control unit 4c determines that the flow of air is generated.

Furthermore, the control unit 4c performs not only the control of the amount of the blown air but also the control of air-conditioning temperature. For example, while ensuring the amount of the blown air where the temperature gradient is equal to or larger than a predetermined gradient, the control unit 4c controls the temperature of the refrigerant of the heat exchanger 4b so that the temperatures A₁, A₂, and A₃ detected by the sensors 13 are close to the predetermined temperature T₂, T₂, and T₃. The control of the amount of the blown air corresponds to an operation for changing the gradient of the graph of FIG. 4C, and the control of air-conditioning temperature corresponds to an operation for changing the position of the graph in a direction of a vertical axis (that is, an operation for translating the graph in a vertical direction). Accordingly, the control of the amount of the blown air and the control of air-conditioning temperature can be performed independently of each other. For example, both the controls maybe simultaneously performed. Alternatively, after one of the controls is completed, the other thereof may be started.

### 5. Flowchart

FIG. 5 is a flowchart exemplifying the flow of control of the amount of the blown air that is performed by this embodiment. Each step in this flowchart is repeatedly performed in the control unit 4c of the air-conditioning device 4 at a predetermined cycle. Steps A10 to A90 are steps mainly relating to the control of the amount of the blown air, and Steps A100 to A160 are steps mainly relating to the control of air-conditioning temperature.

In Step A10, temperatures A₁, A₂, and A₃ in the rectifying unit 2 are detected by three sensors 13a to 13c and information of the temperatures is transmitted to the control unit 4c. In succeeding Step A20, a temperature difference A₂−A₁ between the sensors 13a and 13b is calculated as a temperature gradient R₁ and a temperature difference A₃−A₂ between the sensors 13b and 13c is calculated as a temperature gradient R₂.

In Step A30, it is determined whether or not the temperature gradients R₁ and R₂ calculated in the previous step are equal to or larger than a predetermined value R_{TH}. Here, if “R₁≧R_{TH}” and “R₂≧R_{TH}” are satisfied, the flow proceeds to Step A40. In Step A40, it is determined that the flow of air is not generated in the rectifying unit 2, that is, an air volume balance is good. In this case, the amount of the blown air is not changed, the amount of air, which is equal to the amount of the blown air having been maintained until the previous time, is maintained, and the flow proceeds to Step A100.

Meanwhile, if “R₁<R_{TH}” or “R₂<R_{TH}” is satisfied in Step A30, the flow proceeds to Step A50. In Step A50, it is determined that the flow of air is generated in the rectifying unit 2, and the direction of the flow of air is determined using at least one of the temperatures A₁, A₂, and A₃ detected by the sensors 13. For example, it is determined whether or not the temperature A₁ detected by the sensor 13a disposed close to the cold aisle 6 is equal to or higher than the predetermined temperature T₁. Here, if “A₁≧T₁” is satisfied, the flow proceeds to Step A60 and it is determined that there is air flow from the hot aisle 7 to the cold aisle 6. Accordingly, in Step A70 following Step A60, the amount of the blown air is corrected to be increased. Meanwhile, when the temperature A₁ is lowered by this operation, the flow of air from the hot aisle 7 to the cold aisle 6 is weakened. Accordingly, the temperature gradients R₁ and R₂ are increased. As a result, the temperature gradients R₁ and R₂ are changed to be close to the predetermined value R_{TH}.

Further, if a determination result of Step A50 satisfies “A₁<T₁”, the flow proceeds to Step A80 and it is determined that there is air flow from the cold aisle 6 to the hot aisle 7. Accordingly, in Step A90 following Step A80, the amount of the blown air is corrected to be reduced. When the temperature A₁ is raised by this operation, the flow of air from the cold aisle 6 to the hot aisle 7 is weakened. Accordingly, the temperature gradients R₁ and R₂ are increased. As a result, even in this case, the temperature gradients R₁ and R₂ are changed to be close to the predetermined value R_{TH}.

In Step A100 and subsequent steps that follow Steps A40, A70, and A90, air-conditioning temperature is controlled. First, in Step A100, the cooling capacity (cooling efficiency) of the air-conditioning device 4 is determined using at least one of the temperatures A₁, A₂, and A₃ in the rectifying unit 2. For example, an average value A_{AVE} of the temperatures A₁, A₂, and A₃ is calculated (that is, A_{AVE}=(A₁+A₂+A₃)/3) and it is determined whether or not the average value A_{AVE} is in a predetermined range of A_{MIN} to A_{MAX}. Here, if “A_{MIN}≦A_{AVE}≦A_{MAX}” is satisfied, the flow proceeds to Step A110 and it is determined that air-conditioning temperature is good. In this case, air-conditioning temperature is not changed, the same temperature as the air-conditioning temperature, which has been maintained until the previous time, is maintained, and the flow is ended.

Meanwhile, if “A_{MIN}>A_{AVE}” or “A_{AVE}>A_{MAX}” is satisfied in Step A100, the flow proceeds to Step A120. In Step A120, it is determined that air-conditioning temperature is not good and the change direction of air-conditioning temperature is determined using at least one of the temperatures A₁, A₂, and A₃ detected by the sensors 13. For example, it is determined whether or not the average value A_{AVE}, which is calculated in the previous step, is equal to or larger than a predetermined value A_{Q}. Here, if “A_{AVE}≧A_{Q}” is satisfied, the flow proceeds to Step A130 and it is determined that air-conditioning temperature is high. Accordingly, in Step A140 following Step A130, the temperature of the refrigerant of the heat exchanger 4b is corrected so that air-conditioning temperature is lowered, and the flow is ended. When all the temperatures A₁, A₂, and A₃ are lowered by this operation, the average value A_{AVE} is also lowered and is changed so as to be in the predetermined range of A_{MIN} to A_{MAX}.

Further, if a determination result of Step A120 satisfies “A_{AVE}<A_{Q}”, the flow proceeds to Step A150 and it is determined that air-conditioning temperature is low. Accordingly, in Step A160 following Step A150, the temperature of the refrigerant of the heat exchanger 4b is corrected so that air-conditioning temperature is raised, and the flow is ended. When the temperatures A₁, A₂, and A₃ are raised as a whole by this operation, the average value A_{AVE} is also raised and is changed so as to be in the predetermined range of A_{MIN} to A_{MAX} even in this case.

### 6. Effect

As described above, according to the air-conditioning system of this embodiment, the following effects are obtained.

(1) Since static sensors detecting temperature or pressure are used instead of dynamic sensors detecting the flow velocity or the flow rate of air, it is possible to simply and inexpensively find out the flow of air in the rectifying unit 2 as compared to the case of the first embodiment, to improve the accuracy of the control of the amount of air supplied to the cold aisle 6, and to further improve cost performance.

(2) Further, the above-mentioned air-conditioning system finds out a temperature gradient in the rectifying unit 2 by the three sensors 13 that are provided along the tubular axis of the rectifying unit 2. It is possible to observe the change of temperature or pressure with high accuracy by such a calculation, and to improve the accuracy of estimation of the moving state of air flow.

(3) Furthermore, since not only the amount of the blown air but also air-conditioning temperature is controlled in the above-mentioned air-conditioning system, it is possible to perform cooling control without excess and deficiency according to a load of the IT devices 5.

According to the disclosed technique, it is possible to improve the controllability of the air-conditioning system by the appropriate control of the amount of air.

### 7. Modification

The first and second embodiments have been described above, but a specific embodiment is not limited to the first and second embodiments. The above-mentioned server room 10 has the space under the floor and the attic as a space for air-conditioning. But there is no guarantee that every server room 10 has such a space. Tubular ducts, which have a function as the space under the floor and the attic, may be connected to the cold aisles 6 and the hot aisles 7.

Further, IT devices or server racks, which take in the blown air from the front surfaces 5b thereof and discharge heat to the back surfaces 5c, have been assumed as the IT devices 5. However, the heat discharge structure, the housing structure, the shape, and the like of the IT devices 5 are arbitrary. If a device takes in the blown air from at least one side thereof and discharges heat to the other side thereof, the device is applied as an object of which air-conditioning is to be managed like the IT devices 5. Specifically, the air-conditioning system may be applied as the cooling system of a server machine that takes in the blown air from the side surfaces of housing and discharges heat to an upper surface of the housing.

Furthermore, the cross-sectional shape of the rectifying unit 2 has been the shape of a square tube, but various shapes are considered as the shape of the rectifying unit 2. For example, the rectifying unit 2 may be formed in the shape of a hollow circular tube as illustrated in FIG. 3B, and may be formed in the shape of a variable duct member of which the tube surface is formed in the shape of a bellows. Moreover, not only a tubular body of which a tubular axis is linear but also a tubular body of which a tubular axis is bent may be applied. In addition, a tubular body of which the cross-sectional shape of a hollow portion is not constant in the direction of a tubular axis may be used, and the rectifying units may be disposed so that the tubular axis of the rectifying unit 2 is not perpendicular to the wall surface of the dividing wall 1.

As long as the flow direction of air near at least a sensor element of the sensor 3 is constant, other portions except for the vicinity of the sensor element can be formed in an arbitrary shape. Meanwhile, in the control of the air-conditioning system, the amount of the blown air is controlled so that air hardly flows in the rectifying unit 2. In other words, control target values of the flow velocity and the flow rate of air in the rectifying unit 2 are zero. Accordingly, the control of the air-conditioning system can be performed even though the rectifying unit 2 has a shape in which the flow velocity or the flow rate of air in the rectifying unit 2 is changed (for example, a shape in which the cross-sectional area of the hollow portion is changed in the direction of a tubular axis).

Further, various patterns of the number, the disposition, and the sizes of the rectifying units 2 to be installed are also considered. For example, rectifying units 2 may be horizontally arranged in a row along the surface of the dividing wall 1 as illustrated in FIG. 3C. The dimensions of the opening portion 1a and the hollow portion of the rectifying unit 2 may be appropriately set according to the size of the sensor 3 or the sensor element.

Meanwhile, control, which uses temperature as static sensors (state detectors), has been described in the second embodiment, but the same control can be performed even when pressure sensors are used instead of the temperature sensors. Meanwhile, when pressure sensors are used, a method of finding out a pressure gradient in the rectifying unit 2 may be used but the flow velocity of air maybe calculated using a pressure difference.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An air-conditioning system comprising:
a divider that divides a cold aisle and a hot aisle in a chamber in which an information technology device is to be enclosed;
a rectifier formed in a shape of a hollow tube and provided so as to penetrate the divider;
a detector that is built into the rectifier and detects airflow passing through the rectifier; and
a controller that controls an amount of air supplied to the cold aisle using detection results of the detector.

2. The air-conditioning system according to claim 1, wherein the detector includes a motion detector that detects a flow velocity or a flow rate of the airflow.

3. The air-conditioning system according to claim 1, wherein the detector includes a state detector that detects temperature or pressure in the rectifier.

4. The air-conditioning system according to claim 3, wherein a plurality of state detectors are provided along a tubular axis of the rectifier, and
the controller controls the amount of air using a difference between a plurality of detection results detected by the state detectors.

5. The air-conditioning system according to claim 4, wherein the controller controls a temperature of air supplied to the cold aisle using detection values detected by the state detectors, and controls an amount of air using a difference between the detection values.

6. The air-conditioning system according to claim 1, wherein the rectifier includes a tubular axis perpendicular to a dividing surface of the divider.
